(19) United States
(12) Patent Application Publication
(10) Pub. No.: US 2023/0123274 A1
(43) Pub. Date: Apr. 20, 2023

(54) SEMICONDUCTOR DEVICES HAVING STRESSED ACTIVE REGIONS THEREIN THAT SUPPORT ENHANCED CARRIER MOBILITY

(71) Applicant: Samsung Electronics Co., Ltd., Suwon-si (KR)

(72) Inventor: Woo-Bin Song, Hwaseong-si (KR)

(21) Appl. No.: 17/731,615

(22) Filed: Apr. 28, 2022

(30) Foreign Application Priority Data
Oct. 15, 2021 (KR) 10-2021-0137382

(51) Int. Cl. H01L 29/76; H01L 29/06; H01L 29/24; H01L 29/423; H01L 29/45; H01L 29/49; H01L 29/786

(52) U.S. Cl. CPC H01L 29/7606; H01L 29/0665; H01L 29/24; H01L 29/42392; H01L 29/45; H01L 29/4908; H01L 29/78696

(57) ABSTRACT

A semiconductor device includes a substrate, a first insulating layer on the substrate, source and drain patterns at spaced-apart locations on the first insulating layer, and a channel layer having a transition metal therein, such as a transition metal dichalcogenide. The channel layer extends on the first insulating layer and between the source and drain patterns. A second insulating layer is also provided, which extends on the channel layer and has a thickness less than a thickness of the first insulating layer. A gate structure is provided, which extends on the second insulating layer, and opposite the channel layer. The channel layer may include at least one of MoS₂, WS₂, MoSe₂, WSe₂, MoSe₂, WTe₂, and ZrSe₂.

### REFERENCE TO PRIORITY APPLICATION

This application claims priority to Korean Patent Application No. 10-2021-0137382, filed Oct. 15, 2021, the disclosure of which is hereby incorporated herein by reference.

### BACKGROUND

The present inventive concept relates to semiconductor devices that utilize compressive and tensile stresses to enhance device performance.

In order to improve performance of a semiconductor device, research is being conducted to increase mobility of charge carriers and/or to reduce resistance of a source/drain region. In addition, to overcome limitations in electrical characteristics (e.g., a short channel effect and the like) of a semiconductor device in response to decreases in size of the semiconductor device, as a degree of integration of a semiconductor chip increases, efforts to develop semiconductor devices having three-dimensional active regions, such as FinFETs, have been pursued.

### SUMMARY

An aspect of the present inventive concept is to provide semiconductor devices having improved electrical characteristics.

According to an embodiment of the present inventive concept, a semiconductor device includes: (i) a substrate, (ii) a first insulating layer extending on the substrate, (iii) a source pattern and a drain pattern, which are arranged on the first insulating layer and spaced apart from each other, (iv) a channel layer including a transition metal, which extends on the first insulating layer between the source pattern and the drain pattern, (v) a second insulating layer, which extends on the channel layer and is thinner than the first insulating layer, and (vi) a gate structure extending on the second insulating layer.

According to another embodiment of the inventive concept, a semiconductor device includes a substrate, a first insulating layer extending on the substrate, and source and drain patterns arranged on the first insulating layer and spaced apart from each other in a first direction, which is parallel to an upper surface of the substrate. A channel layer is also provided, which extends on the first insulating layer and between the source pattern and the drain pattern. The channel layer may include a material having a two-dimensional planar structure. A gate structure is provided, which extends in a second direction that is perpendicular to the first direction, intersects the channel layer on the substrate, and covers at least an upper surface and side surfaces of the channel layer.

According to another embodiment of the present inventive concept, a semiconductor device includes: (i) a substrate, (ii) a plurality of channel layers, which include a transition metal and are spaced apart from each other in a first direction that is perpendicular to the substrate, (iii) a source pattern and a drain pattern, arranged on both sides of the plurality of channel layers to contact the plurality of channel layers, and (iv) a gate structure extending in a second direction, intersecting the plurality of channel layers on the substrate, and surrounding the plurality of channel layers. The gate structure may include a gate insulating layer surrounding side surfaces of the channel layers and including hexagonal boron nitride (h-BN), a gate dielectric layer surrounding an outer side surface of the gate insulating layer, and a gate electrode layer surrounding an outer side surface of the gate dielectric layer.

According to another embodiment of the present inventive concept, a semiconductor device includes a substrate, a first insulating layer extending on the substrate, a source pattern extending on the first insulating layer, and a drain pattern extending above the substrate and spaced apart from the source pattern in a first direction, perpendicular to an upper surface of the substrate. A channel layer is also provided, which extends in a first direction and between the source pattern and the drain pattern, and includes a transition metal. A gate insulating layer is provided, which extends between the source pattern and the drain pattern and surrounds a side surface of the channel layer. A gate dielectric layer is provided, which extends between the source pattern and the drain pattern, and surrounds an outer side surface of the gate insulating layer. A gate electrode layer is provided, which extends between the source pattern and the drain pattern, and surrounds at least an outer side surface of the gate dielectric layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to example embodiments.

FIGS. 2, 3A-3B, and 4 to 6 are cross-sectional views illustrating semiconductor devices according to example embodiments.

FIG. 7 is a plan view illustrating a semiconductor device according to example embodiments.

FIGS. 8 to 10 are cross-sectional views illustrating semiconductor devices according to example embodiments.

FIG. 11 is a plan view illustrating a semiconductor device according to example embodiments.

FIGS. 12, 13A-13B, 14A-14B and 15A-15B are cross-sectional views illustrating semiconductor devices according to example embodiments.

FIG. 16 is a cross-sectional view illustrating a semiconductor device according to example embodiments.

### DETAILED DESCRIPTION

Hereinafter, preferred embodiments of the present inventive concept will be described with reference to the accompanying drawings.

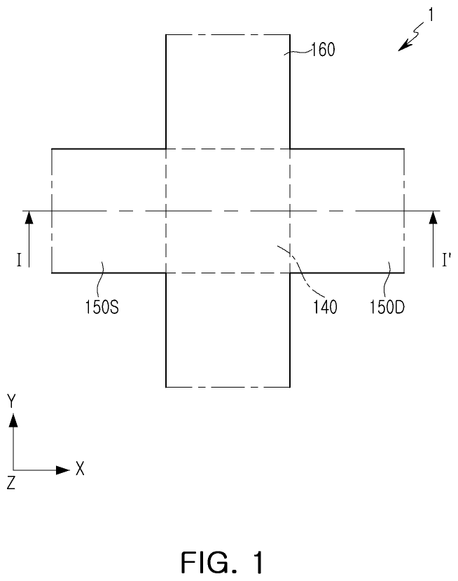

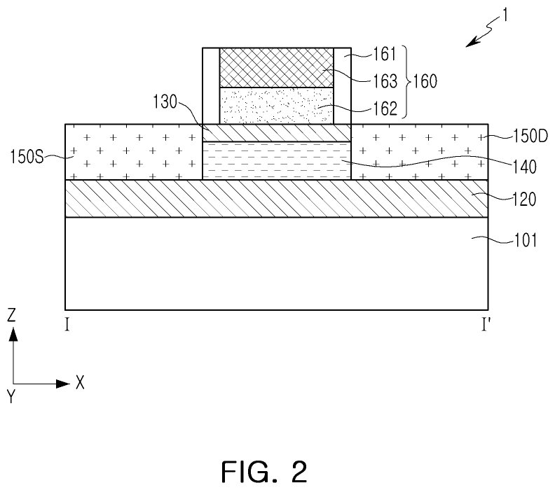

FIG. 1 is a plan view illustrating a semiconductor device according to example embodiments, and FIG. 2 is a cross-sectional view illustrating a semiconductor device according to example embodiments. In particular, FIG. 2 illustrates a cross-sectional view of the semiconductor device of FIG. 1, taken along line I-I′. For convenience of description, only major components of the semiconductor device are illustrated in FIGS. 1 and 2.

Referring to FIGS. 1 and 2, a semiconductor device 1 may include a substrate 101, a first insulating layer 120 disposed on the substrate, a source pattern 150S and a drain pattern 150D, arranged on the first insulating layer 120 and spaced apart from each other, a channel layer 140 disposed on the first insulating layer 120 between the source pattern 150S and the drain pattern 150D, a second insulating layer 130 disposed on the channel layer 140, and a gate structure 160 disposed on the second insulating layer 130. The first insulating layer 120, the source pattern 150S and the drain pattern 150D, the channel layer 140, the second insulating layer 130, and the gate structure 160 may constitute a transistor (e.g., field effect transistor). Hereinafter, the transistor will be treated as an NMOS transistor, unless otherwise stated.

The substrate 101 may have an upper surface extending in X and Y directions. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOl) layer, or the like.

The channel layer 140 may be disposed above the substrate 101. The channel layer 140 may include a material comprised of a single layer of atoms, molecules or cells (hereinafter, referred to as a 2D material). 2D material may have a layered structure. For example, the channel layer 140 may include transition metal dichalcogenides having a chemical formula of MX₂ (where, M is a transition metal and X is a chalcogen element). The channel layer 140 may have a layered structure, in which a plane of M atoms is sandwiched by planes of X atoms. The channel layer 140 may have a thickness of no more than three atomic layers. For example, the channel layer 140 may include one or more of molybdenum disulfide (MoS₂), tungsten disulfide (WS₂), molybdenum diselenide (MoSe₂), tungsten diselenide (WSe₂), tungsten ditelluride (WTe₂), and zirconium diselenide. (ZrSe₂). The transition metal and the chalcogen element are not limited thereto. The 2D material may be provided as a thin monolayer of atoms, molecules or cells. Therefore, in the channel layer 140 including the 2D material, it is advantageous to suppress a short channel effect, compared to a channel layer including other materials, and in particular, it is advantageous to improve performance for devices having a scale of 1 nm (i.e., 10A) or less.

The first insulating layer 120 and the second insulating layer 130 may be respectively disposed above and below the channel layer 140. In an embodiment, the first insulating layer 120 may be disposed between the upper surface of the substrate 101 and a lower surface of the channel layer 140, and may be disposed to cover the lower surface of the channel layer 140. In an embodiment, the first insulating layer 120 may extend to entirely cover the upper surface of the substrate 101. The second insulating layer 130 may be disposed between an upper surface of the channel layer 140 and a lower surface of the gate structure 160, and may extend to cover at least the upper surface of the channel layer 140.

The first insulating layer 120 and the second insulating layer 130 may include the same material. For example, the first and second insulating layers 120 and 130 may include a 2D material, such as a 2D material including heterogeneous elements having a molar ratio of 1:1. For example, the first and second insulating layers 120 and 130 may include hexagonal boron nitride (h-BN). A thermal expansion coefficient of the hexagonal boron nitride included in the first insulating layer 120 and the second insulating layer 130 may have a different value from that of the 2D material included in the channel layer 140. For example, when a semiconductor device 1 according to an embodiment of the present inventive concept is an N-type metal oxide semiconductor (NMOS), the first and second insulating layers 120 and 130 may have a thermal expansion coefficient, higher than a thermal expansion coefficient of the channel layer 140. Therefore, when a temperature increases due to driving of the semiconductor device 1, the first and second insulating layers 120 and 130 may have compressive stresses, and a tensile stress may be applied to the channel layer 140. Therefore, the mobility of a carrier (e.g., electron) in the channel layer 140 to which the tensile stress is applied may increase, and an on-current of the transistor may be improved.

The thermal expansion coefficients of the first and second insulating layers 120 and 130 may be changed by controlling a thickness of the hexagonal boron nitride. Also, the first insulating layer 120 and the second insulating layer 130 may have different thicknesses. For example, the first insulating layer 120 may have a thickness, greater than a thickness of the second insulating layer 130. When the thickness of the first insulating layer 120 is greater than the thickness of the second insulating layer 130, as a temperature of the semiconductor device 1 increases, a compressive stress applied to the first insulating layer 120 may be greater than a compressive stress applied to the second insulating layer 130. Therefore, a bending stress may be applied to the first insulating layer 120 due to a difference in compressive stress between the first insulating layer 120 and the second insulating layer 130. For example, a greater compressive stress may be applied to a surface of the first insulating layer 120 facing the channel layer 140. As a result, a tensile stress applied to the channel layer 140 (disposed between the first insulating layer 120 and the second insulating layer 130) may further increase. Therefore, the electron mobility in the channel layer 140 may further increase.

The thickness of the second insulating layer 130 may be about 3 Å to about 30 Å greater than the thickness of the first insulating layer 120. When a difference in thickness between the first insulating layer 120 and the second insulating layer 130 is less than the above range, the tensile stress applied to the channel layer 140 by the first and second insulating layers 120 and 130 may not be sufficiently large. Alternatively, when the difference in thickness exceeds the above range, there may be a restriction in miniaturization of the device or the efficiency of the process may be deteriorated.

The first and second insulating layers 120 and 130 may include hexagonal boron nitride, to dissipate unnecessary heat generated during an operation of the semiconductor device 1. As illustrated in FIG. 2, the first and second insulating layers 120 and 130 may have a planar structure. The hexagonal boron nitride included in the first and second insulating layers 120 and 130 may have a thermal conductivity of, for example, about 550 W/(m·K) to about 650 W/(m·K) in an in-plane direction (an X-Y plane direction). The hexagonal boron nitride included in the first and second insulating layers 120 and 130 may have a thermal conductivity of about 25 W/(m·K) to about 35 W/(m·K) in an out-of-plane direction (e.g., a Z-axis direction, perpendicular to the X-Y plane). For this reason, a problem in which the semiconductor device 1 is self-heated may be solved by disposing the first and second insulating layers 120 and 130 to contact the lower and upper surfaces of the channel layer 140, respectively, and dissipating unnecessary heat generated during driving of the semiconductor device 1 in a planar direction (e.g., the X-Y direction). In addition, the first insulating layer 120 disposed between the substrate 101 and the source and drain patterns 150S and 150D may prevent leakage current. For example, the hexagonal boron nitride included in the first and second insulating layers 120 and 130 may also function as an electrical insulator.

The source pattern 150S and the drain pattern 150D may be disposed on the first insulating layer 120, and may be spaced apart from each other to contact both ends of the channel layer 140. In an embodiment, the source and drain patterns 150S and 150D may include a metal material, and may include, for example, one or more of gold (Au), copper (Cu), nickel (Ni), silver (Ag), aluminum (Al), molybdenum (Mo), chromium (Cr), tantalum (Ta), titanium (Ti), and tungsten (W). The source and drain patterns 150S and 150D may also include, for example, one or more of titanium (Ti) and tungsten (W). Since the source and drain patterns 150S and 150D include the above-described metal material, compressive stress may act on the source and drain patterns 150S and 150D, and in particular, compressive stress may act in the in-plane direction (the X-Y plane direction). The compressive stress acting on the source and drain patterns 150S and 150D may apply tensile stress to the channel layer 140 disposed between the source and drain patterns 150S and 150D. For example, the tensile stress due to the compressive stress of the source and drain patterns 150S and 150D may act on the channel layer 140 of which both ends are in contact with side surfaces of the source and drain patterns 150S and 150D. Therefore, electron mobility in the channel layer 140 may increase, and on-current characteristics of the transistor may be improved.

In an embodiment, the source and drain patterns 150S and 150D may include a 2D material doped with impurities. The 2D material may include a dopant such as chromium (Cr), aluminum (Al), molybdenum (Mo), tungsten (W), titanium (Ti), or the like, to increase compressive stress. For example, the source and drain patterns 150S and 150D may include molybdenum diselenide (MoSe₂) doped with about 10 at % to 50 at % of chromium (Cr), where at % corresponds to atomic percent. Depending on a type of the 2D material in which the source and drain patterns 150S and 150D include, a type of dopant, a doping concentration, or the like may be changed. In addition, desirable compressive strength characteristics of the source and drain patterns 150S and 150D may be obtained by controlling a lattice size of the 2D material.

The gate structure 160 may cross the channel layer 140 on the substrate 101, and may extend to cover the channel layer 140. In an embodiment, the gate structure 160 may include a gate dielectric layer 162 disposed on the second insulating layer 130, a gate electrode layer 163 disposed on the gate dielectric layer 162, and gate spacer layers 161 (a/k/a “sidewall spacers”) on side surfaces of the gate electrode layer 163 (and gate dielectric layer 162).

The gate electrode layer 163 may include a conductive material, and may include, for example, at least one of a metal nitride (e.g., at least one of titanium nitride (TiN), tantalum nitride (TaN), or tungsten nitride (WN)), a metal material (e.g., at least one of aluminum (Al), tungsten (W), or molybdenum (Mo)), or silicon (e.g., doped polysilicon).

The gate electrode layer 163 may be formed as two or more multilayer structures. The gate spacer layers 161 may be disposed on the side surfaces of the gate electrode layer 163. The gate spacer layers 161 may insulate the source and drain patterns 150S and 150D and the gate electrode layer 163. The gate spacer layers 161 may have a multi-layer structure according to embodiments. The gate spacer layers 161 may include at least one of an oxide, a nitride, an oxynitride, or a low-k dielectric.

The gate dielectric layer 162 may be disposed to cover at least a portion of the second insulating layer 130 on the channel layer 140. In an embodiment, the gate dielectric layer 162 may include at least one of a ferroelectric material film having ferroelectric properties or a paraelectric material film having paraelectric properties. The semiconductor device 1 may include a negative capacitance (NC) FET using a negative capacitor.

The ferroelectric material film may have negative capacitance, and the paraelectric material film may have positive capacitance. For example, when two or more capacitors may be connected in series, and capacitance of each of the capacitors has a positive value, overall capacitance may be decreased than individual capacitance of each of the capacitors. However, when capacitance of at least one of two or more capacitors connected in series has a negative value, overall capacitance having a positive value may be greater than an absolute value of each individual capacitance.

And, when the ferroelectric material film having negative capacitance and the paraelectric material film having positive capacitance are connected in series, an overall capacitance value of the ferroelectric material film and the paraelectric material film, connected in series, may increase. Since the increase in the overall capacitance value may be used, a transistor including the ferroelectric material film may have a sub-threshold swing (SS) of less than 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, or lead zirconium titanium oxide. In this case, as an example, hafnium zirconium oxide may be a material in which zirconium (Zr) is doped into hafnium oxide. As another example, hafnium zirconium oxide may be a compound of hafnium (Hf), zirconium (Zr), and oxygen (O).

The ferroelectric material film may further include a dopant. For example, a dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). Depending on which ferroelectric material is included in the ferroelectric material film, a type of dopant included in the ferroelectric material film may be changed.

When the ferroelectric material film includes hafnium oxide, the dopant included in the ferroelectric material film may include, for example, at least one of gadolinium (Gd), silicon (Si), zirconium (Zr), aluminum (Al), or yttrium (Y). When the dopant is aluminum (Al), the ferroelectric material film may contain about 3 at % to about 8 at % of aluminum, and may be annealed at a temperature ranging from about 800° C. to about 1000° C. In this case, a ratio of the dopant may be a ratio of aluminum to a sum of hafnium and aluminum.

When the dopant is silicon (Si), the ferroelectric material film may contain about 2 at % to about 10 at % of silicon, and may be annealed at a temperature ranging from about 650° C. to 1000° C. When the dopant is yttrium (Y), the ferroelectric material film may contain about 2 at % to about 10 at % of yttrium, and may be annealed at a temperature ranging from about 600° C. to about 1000° C. When the dopant is gadolinium (Gd), the ferroelectric material film may contain about 1 at % to about 7 at % gadolinium, and may be annealed at a temperature ranging from about 450° C. to about 800° C. When the dopant is zirconium (Zr), the ferroelectric material film may contain about 50 at % to about 80 at % of zirconium, and may be annealed at a temperature ranging from about 400° C. to about 550° C.

The paraelectric material film may have paraelectric properties. The paraelectric material film may include, for example, at least one of silicon oxide, or a metal oxide having a high dielectric constant. The metal oxide included in the paraelectric material film may include, for example, at least one of hafnium oxide, zirconium oxide, or aluminum oxide, but the present inventive concept is not limited thereto.

The ferroelectric material film and the paraelectric material film may include the same material. The ferroelectric material film may have ferroelectric properties, but the paraelectric material film may not have ferroelectric properties. For example, when the ferroelectric material film and the paraelectric material film include hafnium oxide, a crystal structure of the hafnium oxide included in the ferroelectric material film may be different from a crystal structure of the hafnium oxide included in the paraelectric material film.

The ferroelectric material film may have a thickness having ferroelectric properties. The thickness of the ferroelectric material film may be, for example, about 0.5 nm to about 10 nm, but the present inventive concept is not limited thereto. As will be understood by those skilled in the art, because a critical thickness representing the ferroelectric properties may vary for each ferroelectric material, the thickness of the ferroelectric material film may vary depending on a type of the ferroelectric material.

For example, in some embodiments, the gate dielectric layer 162 may include a ferroelectric material film. As another example, the gate insulating layer may include a plurality of ferroelectric material films spaced apart from each other. The gate dielectric layer 162 may have a stack structure in which a plurality of ferroelectric material films and a plurality of paraelectric material films are alternately stacked.

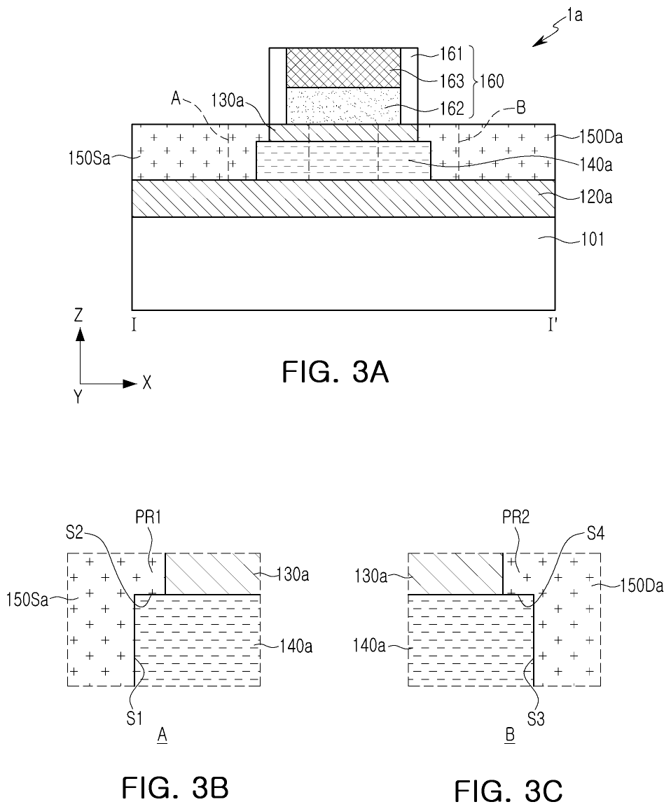

FIGS. 3A-3C and 4 to 6 illustrate modified examples of the semiconductor device according to the example embodiments of FIGS. 1 and 2. In particular, FIGS. 3A-3C and 4 to 6 illustrate alternative embodiments of regions within devices 1a, 1b, 1c, and 1d, which correspond to the cross-sectional view of FIG. 1, taken along line I-I′. In the embodiments of FIGS. 3A-3C and 4 to 6, the same reference numerals as those of FIGS. 1 and 2 indicate configurations corresponding thereto, and descriptions overlapping the above descriptions will be omitted. In the embodiments of FIGS. 3A-3C and 4 to 6, in cases of having the same reference numerals as, but different letters from those of FIGS. 1 and 2, it is illustrated to describe an embodiment, different from those of FIGS. 1 and 2, and features described in the same reference numerals described above may be the same or similar.

Referring to FIGS. 3A-3C, a source pattern 150Sa and a drain pattern 150 Da may include protrusions PR1 and PR2, respectively. A channel layer 140a may be in contact with a lower surface S2 of the protrusion PR1 of the source pattern 150Sa and a side surface S1 of the source pattern 150Sa. The channel layer 140a may be in contact with a lower surface S4 of the protrusion PR2 of the drain pattern 150 Da and a side surface S3 of the drain pattern 150 Da. As such, in the embodiment illustrated in FIGS. 3A-3C, at least a portion of a side surface or an upper surface of the channel layer 140a may be in contact with the source and drain patterns 150Sa and 150 Da. Accordingly, due to the compressive stresses of the source and drain patterns 150Sa and 150 Da, tensile stresses applied to the channel layer 140a may be increased, and electron mobility and on-current characteristics may be further improved.

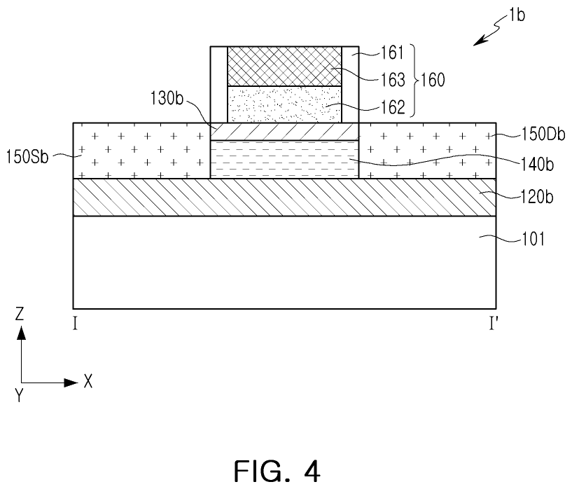

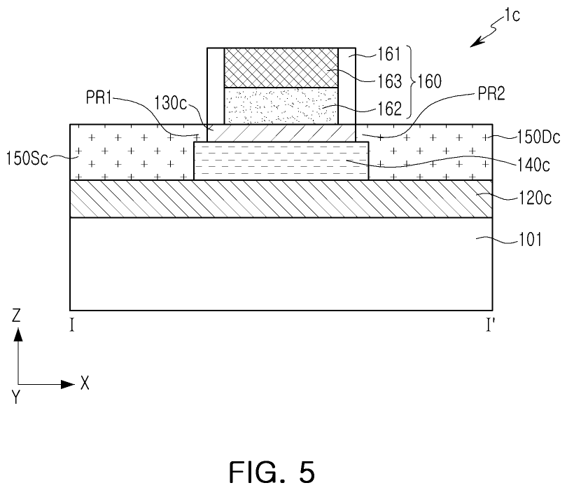

Next, referring to FIG. 4, a second insulating layer 130b may include a material, different from a material of a first insulating layer 120b. For example, the first insulating layer 120b may include hexagonal boron nitride, and the second insulating layer 130b may include a dielectric material such as silicon oxide (SiOₓ), silicon nitride (SiONₓ), or the like. However, in the device 1b of FIG. 4, as compared to the device 1a of FIGS. 3A-3C, tensile stresses applied to a channel layer 140b by compressive stresses of the second insulating layer 130b may be relatively low. Therefore, tensile stresses may be additionally applied to the channel layer 140b by controlling a type and an amount of a metal material included in source and drain patterns 150Sb and 150Db, and/or controlling a type of dopant, a doping concentration, a lattice size, or the like, in a 2D material included in the source and drain patterns 150Sb and 150Db. And, in the device 1c of FIG. 5, source and drain patterns 150Sc and 150Dc may include protrusions PR1 and PR2, respectively, to increase a magnitude of tensile stress applied to a channel layer 140c.

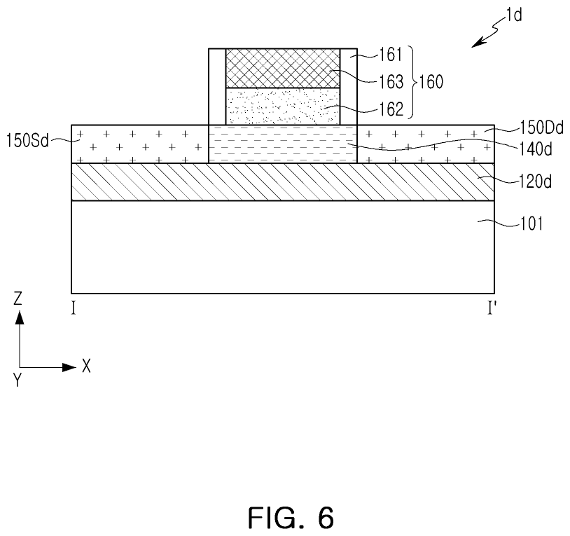

Next, referring to FIG. 6, a semiconductor device 1d may omit a second insulating layer. For example, a lower surface of a channel layer 140d may overlap an upper surface of a first insulating layer 120d containing hexagonal boron nitride, and an upper surface of the channel layer 140d may overlap a lower surface of a gate dielectric layer 162. In an embodiment, both side surfaces of the channel layer 140d may contact source and drain patterns 150Sd and 150Dd, respectively. In an embodiment, upper surfaces of the source and drain patterns 150Sd and 150Dd may be substantially coplanar with the upper surface of the channel layer 140d, as shown.

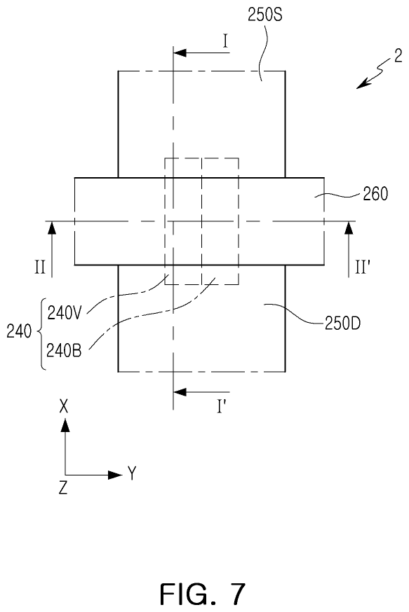

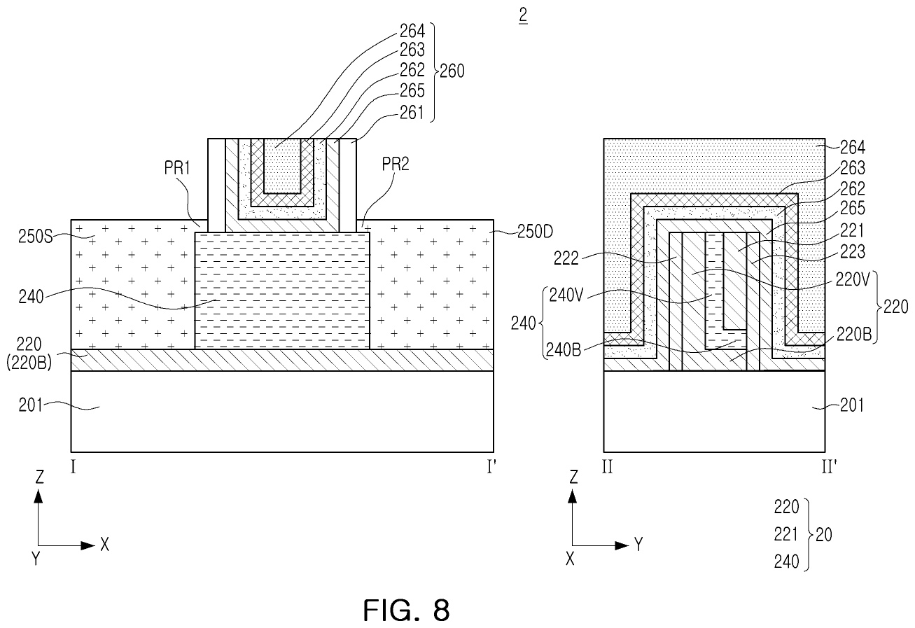

Next, a semiconductor device including a FinFET having a channel having a three-dimensional structure will be described with reference to FIGS. 7 to 10. In particular, FIG. 7 is a plan view illustrating a semiconductor device 2 according to example embodiments, and FIG. 8 is a cross-sectional view illustrating the semiconductor device 2, taken along lines I-I′ and Referring to FIGS. 7 and 8, a semiconductor device 2 may include a substrate 201, first to fourth insulating layers 220, 221, 222, and 223 disposed on the substrate, a source pattern 250S and a drain pattern 250D, arranged on the first insulating layer and spaced apart from each other, a channel layer 240 disposed between the source pattern and the drain pattern, and a gate structure 260 disposed on the channel layer 240. The channel layer 240, the first insulating layer 220, and the second insulating layer 221 may include a portion extending in the first direction (the Z-direction). The semiconductor device 2 may include a fin structure 20 extending in the first direction (the Z-direction) perpendicular to an upper surface of the substrate 201, and including the channel layer 240, the first insulating layer 220, and the second insulating layer 221. Hereinafter, a description overlapping the descriptions described above with reference to FIGS. 1 to 6 will be omitted.

The channel layer 240 may be disposed on the first insulating layer 220 on the substrate 201, and may have a three-dimensional structure. The channel layer 240 may include a vertical channel portion 240V extending in the first direction (e.g., the Z-direction), perpendicular to the upper surface of the substrate 201, and a bottom channel portion 240B extending from a lower end of the vertical channel portion 240V in the second direction (e.g., the X-direction), parallel to the upper surface of the substrate 201. The vertical channel portion 240V and the bottom channel portion 240B of the channel layer 240 may be integrally formed. A height of the vertical channel portion 240V in the first direction (the Z-direction) may be greater than a length of the bottom channel portion 240B in the second direction (the X-direction).

The first insulating layer 220 may be disposed on the substrate 201. The first insulating layer 220 may include a bottom insulating portion 220B disposed between the upper surface of the substrate 201 and a lower surface of the bottom channel portion 240B, and a vertical insulating portion 220V extending from the bottom insulating portion 220B in the first direction (the Z-direction). The vertical insulating portion 220V may extend to be disposed on a side surface of the vertical channel portion 240V connected to a lower surface of the bottom channel portion 240B. The bottom insulating portion 220B and the vertical insulating portion 220V may be integrally formed. The first insulating layer 220 may have a size, different from a size of the channel layer 240, but may have a shape, corresponding to a shape of the channel layer 240, as shown. The first insulating layer 220 may include a 2D material, for example, a 2D material including heterogeneous elements having a molar ratio of 1:1. For example, the first insulating layers 220 may include hexagonal boron nitride (h-BN).

The second to fourth insulating layers 221, 222, and 223 may be disposed on the substrate 201. The second insulating layer 221 may be disposed on an upper surface of the bottom channel portion 240B and a side surface of the vertical channel portion 240V connected to the upper surface of the bottom channel portion 240B. The third insulating layer 222 may be disposed on an outer side surface of the vertical insulating portion 220V of the first insulating layer 220. The fourth insulating layer 223 may be disposed on an outer side surface of the second insulating layer 221. The second to fourth insulating layers 221, 222, and 223 may include the same material as the first insulating layer 220. For example, the second to fourth insulating layers 221, 222, and 223 may include hexagonal boron nitride. Upper surfaces of the first to fourth insulating layers 220, 221, 222, and 223 and an upper surface of the channel layer 240 in the first direction (the Z-direction) may be substantially coplanar.

The gate structure 260 may extend on the substrate 201 to cross the channel layer 240 and cover the channel layer 240. In an embodiment, the gate structure 260 may include a gate insulating layer 265 disposed on the fin structure 20, a gate dielectric layer 262 disposed on the gate insulating layer 265, a work function control layer 263 disposed on the gate dielectric layer, and a gate electrode layer 264 disposed on the work function control layer 263. The gate structure 260 may further include gate spacer layers 261 disposed on side surfaces of the gate insulating layer 265. In an embodiment, the work function control layer 263 may be disposed to surround a lower surface and side surfaces of the gate electrode layer 264, the gate dielectric layer 262 may be disposed to surround a lower surface and side surfaces of the work function control layer 263, and the gate insulating layer 265 may be disposed to surround a lower surface and side surfaces of the gate dielectric layer 262.

The work function control layer 263 may function as a gate electrode together with the gate electrode layer 264, and may include a conductive material such as a metal. The gate insulating layer 265 may include the same material as the first to fourth insulating layers 220, 221, 222, and 223. For example, the gate insulating layer 265 may include hexagonal boron nitride, in some embodiments.

The source and drain patterns 250S and 250D may be disposed on the substrate 201 to be spaced apart from each other, to contact both side surfaces of the channel layer 240. In an embodiment, upper surfaces of the source and drain patterns 250S and 250D may be disposed on a level higher than the upper surface of the channel layer 240. The source and drain patterns 250S and 250D may include protrusions PR1 and PR2 extending from side surfaces thereof contacting the channel layer 240 to cover the upper surface of the channel layer 240, respectively.

As illustrated in the device 2 of FIG. 8, a lower surface of the channel layer 240 may overlap an upper surface of the first insulating layer 220, and the upper surface of the channel layer 240 may overlap a lower surface of the gate insulating layer 265. The first insulating layer 220 and the gate insulating layer 265 may have thermal expansion coefficients, different from a thermal expansion coefficient of the channel layer 240. For example, when a semiconductor device 2 according to an embodiment of the present inventive concept is an N-type metal oxide semiconductor (NMOS), the first insulating layer 220 and the gate insulating layer 265 may have higher thermal expansion coefficients, as compared to a thermal expansion coefficient of the channel layer 240. Therefore, when a temperature increase occurs in response to driving/activating the semiconductor device 2, compressive stresses may be applied to the first insulating layer 220 and the gate insulating layer 265, and tensile stresses may be applied to the channel layer 240. Therefore, electron mobility and on-current through the channel layer 240 may be improved.

In an embodiment, the first insulating layer 220 and the gate insulating layer 265 may include a 2D material, for example, a 2D material including heterogeneous elements having a molar ratio of 1:1. The first insulating layer 220 and the gate insulating layer 265 may include, for example, hexagonal boron nitride. The channel layer 240 may include a 2D material including a transition metal. For example, the channel layer 240 may include transition metal dichalcogenides having a chemical formula of MX₂ (where, M is a transition metal and X is a chalcogen element).

A thickness of the bottom insulating portion 220B of the first insulating layer 220 in the first direction (the Z-direction) may be about 3 Å to about 30 Å greater than a thickness of the gate insulating layer 265 between the lower surface of the gate dielectric layer 262 and the upper surface of the channel layer 240 in the first direction (the Z-direction). Moreover, when a difference in thickness between the bottom insulating portion 220B and the gate insulating layer 265 is less than the above range, tensile stresses applied to the channel layer 240 by the first and second insulating layers 220 and 221 may not be sufficient to provide an advantage in electrical characteristics. Alternatively, when the difference in thickness exceeds the above range, there may be a restriction in miniaturization of the device and/or efficiency of the process may be deteriorated. Advantageously, the first insulating layer 220 and the gate insulating layer 265 may serve to dissipate unnecessary heat generated during an operation of the semiconductor device 2, to solve a problem in which the semiconductor device 2 might otherwise become overheated, and also inhibit leakage currents.

In the embodiments illustrated in FIGS. 7 and 8, since the channel layer 240 has a three-dimensional structure, an area in which the channel layer 240 is in contact with the source and drain patterns 250S and 250D may be large. Therefore, tensile stresses may be sufficiently applied to the channel layer 240 by compressive stress of the source and drain patterns 250S and 250D. In addition, as illustrated in FIG. 8, since the source and drain patterns 250S and 250D may include the protrusions PR1 and PR2, respectively, at least a portion of the upper surface of the channel layer 240 as well as the side surface of the channel layer 240 may be in contact with the source and drain patterns 250S and 250D. Therefore, electron mobility and on-current characteristics in the channel layer 240 may be improved.

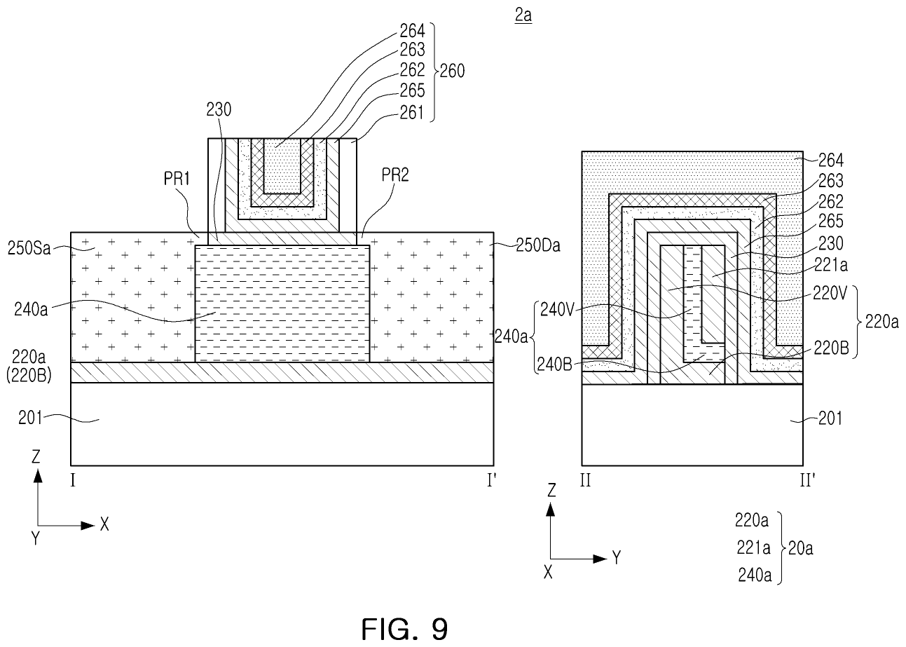

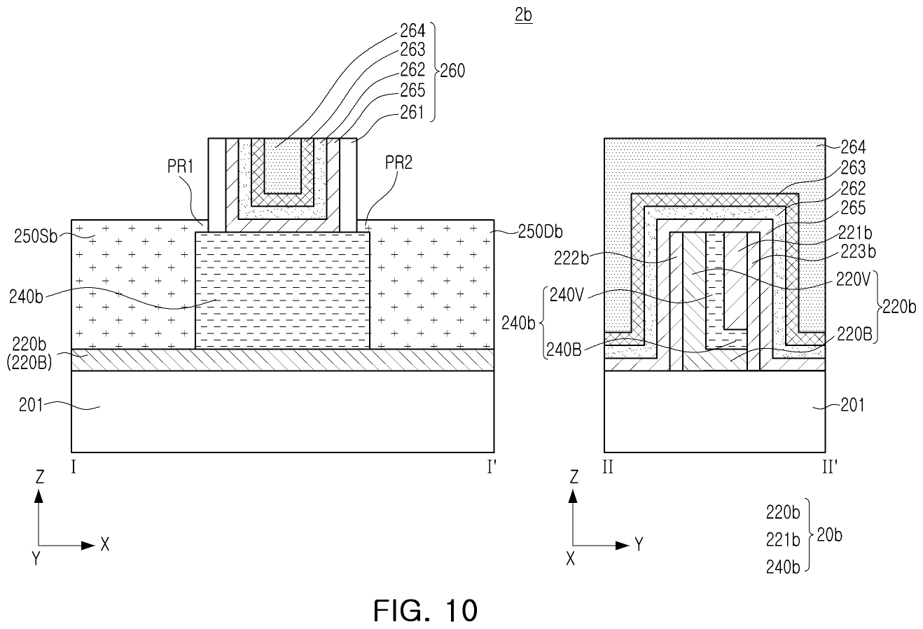

Next, FIGS. 9 and 10 illustrate modified examples of the semiconductor device of FIGS. 7 and 8. In particular, FIGS. 9 and 10 illustrate regions corresponding to the cross-sectional views of FIG. 7, taken along lines I-I′ and II-II′.

In embodiments of FIGS. 9 and 10, the same reference numerals as those of FIGS. 7 and 8 indicate configurations corresponding thereto, and descriptions overlapping the above descriptions will be omitted. In embodiments of FIGS. 9 and 10, in cases of having the same reference numerals as, but different letters (e.g., 2a, 2b) from those of FIGS. 7 and 8, it is illustrated to describe an embodiment(s) different from those of FIGS. 7 and 8, and features described in the same reference numerals described above may be the same or similar.

For example, the semiconductor device 2a of FIG. 9 is different from the semiconductor device 2 of FIG. 8 because it does not include third and fourth insulating layers 222 and 223, and because it further includes an upper insulating layer 230. The upper insulating layer 230 may be formed to surround an upper surface and side surfaces of a fin structure 20a. For this reason, a bottom insulating portion 220B of a first insulating layer 220a may be disposed on a lower surface of a channel layer 240a, and the upper insulating layer 230 and a gate insulating layer 265 may be sequentially arranged on an upper surface of the channel layer 240a.

The first insulating layer 220a, the upper insulating layer 230, and the gate insulating layer 265 may include the same material, and may include, for example, hexagonal boron nitride. The channel layer 240a may include a material having a thermal expansion coefficient that is lower than respective thermal expansion coefficients of the first insulating layer 220a, the upper insulating layer 230, and the gate insulating layer 265, and may include, for example, transition metal dichalcogenides having a chemical formula of MX₂ (where, M is a transition metal and X is a chalcogen element).

Therefore, when a temperature increases due to activation/switching of the semiconductor device 2a, compressive stresses may be applied to the first insulating layer 220a, the upper insulating layer 230, and the gate insulating layer 265, and tensile stresses may be applied to the channel layer 240a. Compared to the previous embodiment of FIG. 8, in the embodiment of FIG. 9, since the upper insulating layer 230 is additionally disposed between the channel layer 240a and the gate insulating layer 265, tensile stresses applied to the channel layer 240a may increase. As a result, electron mobility and on-current characteristics of the channel layer 240a may be further improved, to thereby greatly improve performance of the semiconductor device.

Next, as shown by FIG. 10, a semiconductor device 2b is different from the semiconductor device 2 of FIG. 8 in that second to fourth insulating layers 221b, 222b, and 223b and a gate insulating layer 265 include a different material from that of a first insulating layer 220b. In an embodiment, the first insulating layer 220b may include a 2D material, for example, hexagonal boron nitride, and may include the second to fourth insulating layers 221b, 222b, and 223b and the gate insulating layer 265 may include a dielectric material such as SiO₂, SiONₓ, or the like. Thus, tensile stresses due to compressive stress of the first insulating layer 220b and compressive stress of source and drain patterns 250Sb and 250Db may be applied to a channel layer 240b.

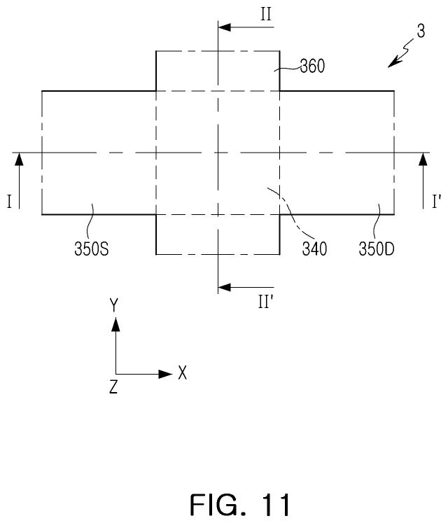

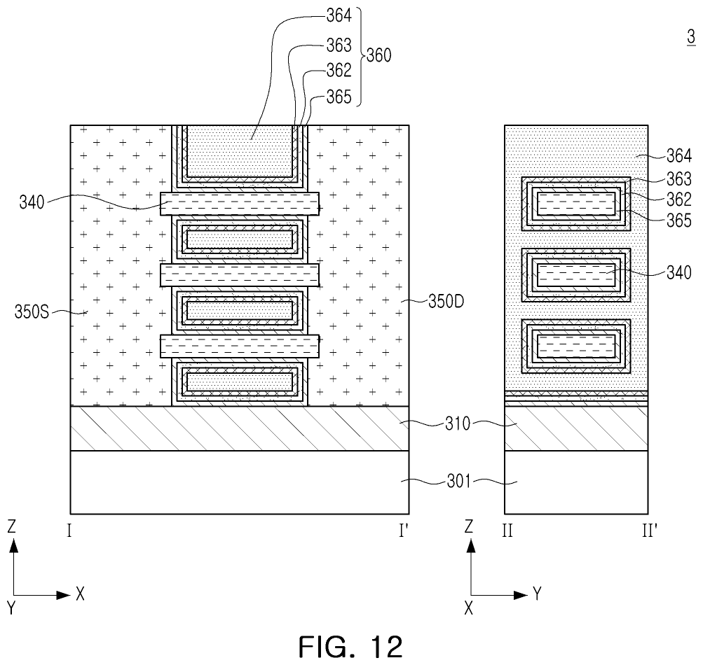

Next, a semiconductor device 3 having a gate-all-around type field effect transistor, particularly a multi-bridge channel FET (MBCFET™) structure, will be described with reference to FIGS. 11 and 12. As shown, FIG. 11 is a plan view illustrating a semiconductor device according to example embodiments, whereas FIG. 12 is a cross-sectional view illustrating a semiconductor device 3 according to example embodiments, where the cross-sectional view is taken along lines I-I′ and II-II′ of FIG. 11.

Referring to FIGS. 11 and 12, a semiconductor device 3 may include a substrate 301, a plurality of channel layers 340 disposed on the substrate 301 to be vertically spaced apart from each other, a gate structure 360 disposed on the substrate 301 and extending to cross the substrate 301, and a source pattern 350S and a drain pattern 350D, contacting the plurality of channel layers 340. The substrate 301 may further include a substrate insulating layer 310.

In the semiconductor device 3, a gate electrode layer 364 may be disposed between an active region and a lowermost channel layer 340, between the plurality of channel layers 340, and on an uppermost channel layer 340. Therefore, the semiconductor device 3 may include a gate-all-around type field effect transistor formed by the plurality of channel layers 340, the source and drain patterns 350S and 350D, and the gate structure 360. Hereinafter, a description overlapping the description described above with reference to FIGS. 1 to 10 will be omitted.

The plurality of channel layers 340 may be disposed to be spaced apart from each other in the first direction (the Z-direction), perpendicular to an upper surface of the active region. The plurality of channel layers 340 may include two or more channel layers. The plurality of channel layers 340 may be spaced apart from the upper surface of the active region while being connected to the source and drain patterns 350S and 350D. The plurality of channel layers 340 may have the same or similar width as the active region in the Y-direction, and may have the same or similar width as the gate structure 360 in the X-direction. In some embodiments, the plurality of channel layers 340 may have a reduced width such that side surfaces thereof are located below the gate structure 360 in the X-direction.

The gate structure 360 may be disposed on the active region and the plurality of channel layers 340 to cross the active region and the plurality of channel layers 340, and extend in one direction, for example, the Y-direction. A channel region of a transistor may be formed in the active region and/or the plurality of channel layers 340, crossing the gate structure 360. The gate structure 360 may include a gate electrode layer 364, and a work function control layer 363, a gate dielectric layer 362, and a gate insulating layer 365, arranged between the gate electrode layer 364 and the plurality of channel layers 340. The gate insulating layer 365 may be disposed to surround the plurality of channel layers 340, the gate dielectric layer 362 may be disposed to surround the gate insulating layer 365, and the work function control layer 363 may be disposed to surround the gate dielectric layer 362, and the gate electrode layer 364 may be disposed to surround the work function control layer 363.

Each of the plurality of channel layers 340 may include a 2D material. For example, the plurality of channel layers 340 may include transition metal dichalcogenides having a chemical formula of MX₂ (where, M is a transition metal and X is a chalcogen element). For example, the plurality of channel layers 340 may include one or more of molybdenum disulfide (MoS₂), tungsten disulfide (WS₂), molybdenum diselenide (MoSe₂), tungsten diselenide (WSe₂), tungsten ditelluride (WTe₂), and zirconium diselenide. (ZrSe₂), but the transition metal and the chalcogen element are not limited thereto.

The gate insulating layer 365 surrounding the plurality of channel layers may include a 2D material, for example, a 2D material including heterogeneous elements having a molar ratio of 1:1. For example, the gate insulating layer 365 may include hexagonal boron nitride (h-BN).

A thermal expansion coefficient of the gate insulating layer 365 may be greater than that of the plurality of channel layers 340. Therefore, when a temperature increases due to driving of the semiconductor device 3, compressive stresses may be applied to the gate insulating layer 365 and tensile stresses may be applied to the plurality of channel layers 340. In the semiconductor device 3 having a multi-bridge channel FET (MBCFET™) structure, a surface of the channel layers 340 excluding a portion contacting the source and drain patterns 350S and 350D may be surrounded by the gate insulating layer 365. Therefore, sufficient tensile stresses may be applied to the plurality of channel layers 340 by the compressive stresses of the gate insulating layer 365, and an electron mobility and on-current characteristics of the device 3 may be greatly improved.

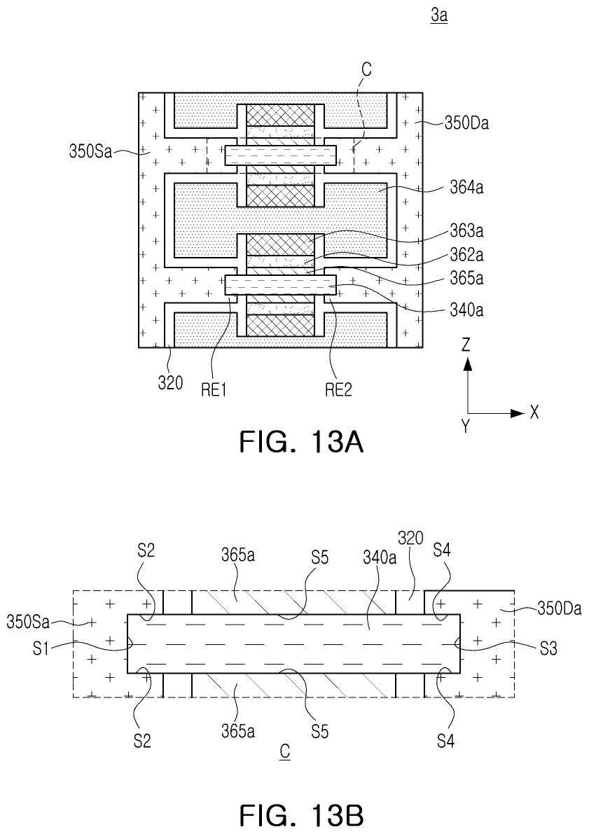

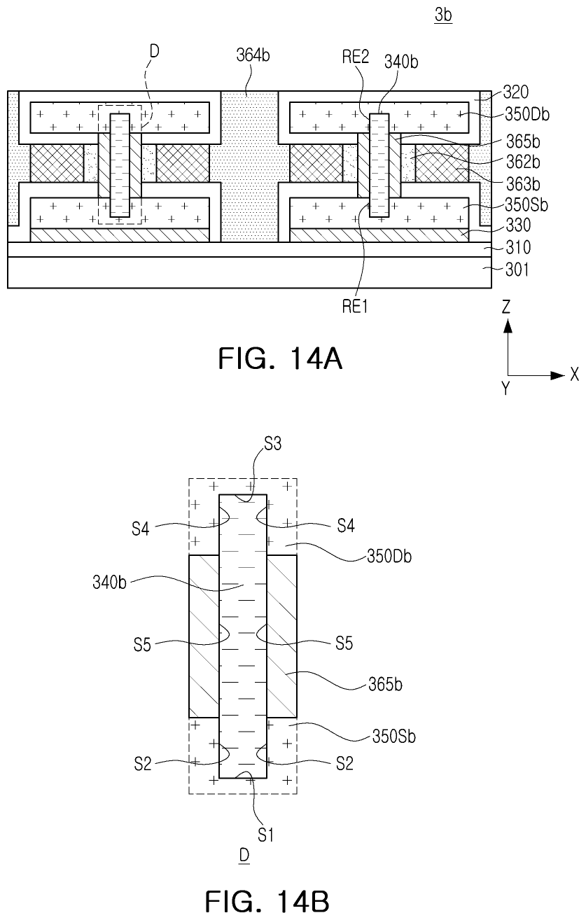

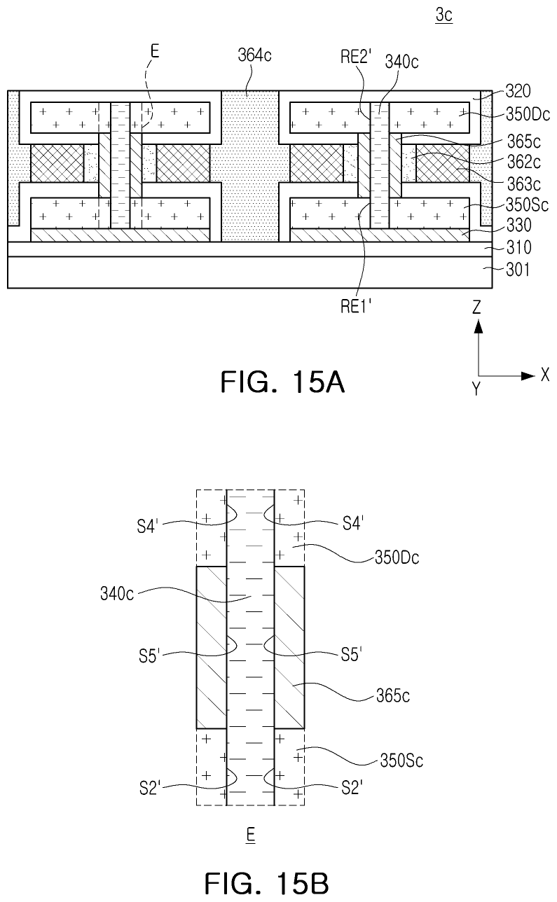

Next, FIGS. 13A-13B, 14A-14B, and 15A-15B illustrate modified examples of the semiconductor device 3 of FIGS. 11 and 12. FIGS. 13A-13B illustrates regions corresponding to the cross-sectional view of FIG. 11, taken along line I-I′, and FIGS. 14A-14B, and 15A-15B illustrate regions corresponding to the cross-sectional view of FIG. 11, taken along line II-II′.

In the embodiments of FIGS. 13A to 15B, the same reference numerals as those of FIGS. 11 and 12 indicate configurations corresponding thereto, and descriptions overlapping the above descriptions will be omitted. In embodiments of FIGS. 13A to 15B, in cases of having the same reference numerals as, but different letters (e.g., 3a, 3b, 3c) from those of FIGS. 11 and 12, it is illustrated to describe an embodiment, different from those of FIGS. 11 and 12, and features described in the same reference numerals described above may be the same or similar.

Referring to FIGS. 13A-13B, a source pattern 350Sa and a drain pattern 350 Da may include recesses RE1 and RE2, respectively. Both end portions of a channel layer 340a may be disposed in the recess RE1 of the source pattern 350Sa and the recess RE2 of the drain pattern 350 Da, respectively. For example, the channel layer 340a may be in contact with a first surface S1 and a second surface S2 of the recess RE1 of the source pattern 350Sa, and may be in contact with a third surface S3 and a fourth surface S4 of the recess RE2 of the drain pattern 350 Da. Also, the channel layer 340a may be in contact with a fifth surface S5 of a gate insulating layer 365a. In an embodiment, the source pattern 350Sa and the drain pattern 350 Da may include a metal material having compressive stress. The gate insulating layer 365a may include a 2D material having compressive stress, and may include, for example, hexagonal boron nitride. Tensile stress may be applied to the channel layer 340a due to compressive stress of the source pattern 350Sa, compressive stress of the drain pattern 350 Da, and compressive stress of the gate insulating layer 365a, contacting the channel layer 340a.

An insulating structure 320 may be additionally disposed between the source pattern 350Sa and a gate electrode layer 364a and between the drain pattern 350 Da and the gate electrode layer 364a. The insulating structure 320 may extend to cover a side surface of the gate insulating layer 365a, a side surface of a gate dielectric layer 362a, and a side surface of a work function control layer 363a.

Next, referring to FIGS. 14A-14B, a semiconductor device 3b may include a substrate 301, a lower insulating layer 330 on the substrate 301, a source pattern 350Sb on the lower insulating layer 330, a drain pattern 350Db disposed above the substrate 301 to be spaced apart from the source pattern 350Sb in a direction, perpendicular to an upper surface of the substrate 301, a channel layer 340b disposed between the source pattern 350Sb and the drain pattern 350Db and extending in the vertical direction (the Z-direction), a gate insulating layer 365b surrounding a side surface of the channel layer 340b, a gate dielectric layer 362b surrounding an outer side surface of the gate insulating layer 365b, and a gate electrode layer 364b surrounding at least an outer side surface of the gate dielectric layer 362b. The semiconductor device 3b may further include a substrate insulating layer 310 disposed on the substrate 301. Also, the semiconductor device 3b may further include a gate contact electrically connected to the gate electrode layer 364b.

The source pattern 350Sb and the drain pattern 350Db may include recesses RE1 and RE2, respectively, and both end portions of the channel layer 340b may be disposed in the recesses RE1 of the source pattern 350Sb and the recess portion RE2 of the drain pattern 350Db, respectively. For example, the channel layer 340b may be in contact with a first surface S1 and a second surface S2 of the recess RE1 of the source pattern 350Sb, and may be in contact with a third surface S3 and a fourth surface S4 of the recess RE2 of the drain pattern 350Db. Also, the channel layer 340b may be in contact with a fifth surface S5 of the gate insulating layer 365b. In an embodiment, the source pattern 350Sb and the drain pattern 350Db may include a metal material having compressive stress. The gate insulating layer 365b may include a 2D material having compressive stress, and may include, for example, hexagonal boron nitride. Tensile stress may be applied to the channel layer 340b due to compressive stress of the source pattern 350Sb, compressive stress of the drain pattern 350Db, and compressive stress of the gate insulating layer 365b, contacting the channel layer 340b.

The lower insulating layer 330 may include a material having compressive stress. The lower insulating layer 330 may include a 2D material, for example, hexagonal boron nitride. The lower insulating layer 330 may apply tensile stress to the channel layer 340b together with the source and drain patterns 350Sb and 350Db.

Next, referring to FIGS. 15A and 15B, an embodiment of FIGS. 15A and 15B is different from the embodiment of FIGS. 14A-14B in that recesses RE1′ and RE2′ of source and drain patterns 350Sc and 350Dc extend to an insulating structure 320. For example, a channel layer 340c may be in contact with a side surface S2′ of the source pattern 350Sc, a side surface S4′ of the drain pattern 350Dc, and a side surface S5′ of a gate insulating layer 365c. Therefore, tensile stress may be applied to the channel layer 340c due to compressive stress of the source pattern 350Sc, compressive stress of the drain pattern 350Dc, and compressive stress of the gate insulating layer 365c, contacting the channel layer 340c.

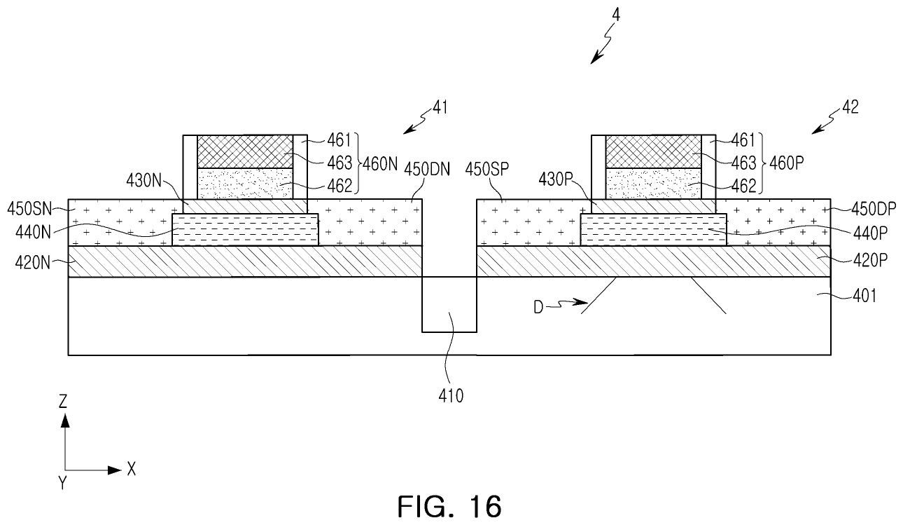

Next, a semiconductor device, such as a complementary metal oxide semiconductor (CMOS) including a negative metal oxide semiconductor (NMOS) and a positive metal oxide semiconductor (PMOS) will be described with reference to FIG. 16. This semiconductor device 4 may be a CMOS including an NMOS 41 and a PMOS 42. The NMOS 41 and the PMOS 42 may have a substrate 401 in common, and may be separated from each other by a device isolation region 410. The device isolation region 410 may be, for example, shallow trench isolation (STI). Hereinafter, a description overlapping the descriptions described above with reference to FIGS. 1 to 15B will be omitted.

The NMOS 41 may include an N-type channel layer 440N, and the PMOS 42 may include a P-type channel layer 440P. In an embodiment, the N-type channel layer 440N and the P-type channel layer 440P may include different 2D materials. For example, the N-type channel layer 440N may include aluminum (Al) as a dopant in molybdenum disulfide (MoS₂), and the P-type channel layer 440P may include molybdenum (Mo) as a dopant in tungsten diselenide (WSe₂). Types of the N-type and P-type channel layers 440N and 440P are not limited thereto. The N-type channel layer 440N may be formed by depositing an aluminum oxide layer (AlOₓ) on molybdenum disulfide (MoS₂) and annealing the same. The p-type channel layer 440P may be formed by depositing a molybdenum oxide layer (MoO₃) on tungsten diselenide (WSe₂) and annealing the same. An annealing temperature may be determined according to a doping concentration of the channel layers, a type of a transition metal, a type of a dopant, or the like.

The PMOS 42 may be similar to the NMOS 41, except that the substrate 401 of the PMOS 42 may include a defect D. The defect D included in the substrate 401 may offset compressive stress toward a central portion of a first insulating layer 420P. Due to this, tensile stress applied to the channel layer 440P from the first insulating layer 420P may be offset, so that hole mobility in the channel layer 440P of the PMOS may not be reduced. For example, according to this embodiment, it is possible to provide the CMOS 4 in which performance of the NMOS 41 is improved and performance of the PMOS 42 is not deteriorated. The defect D included in the substrate 401 of the PMOS 42 may be formed by a stress memory technique (SMT).

According to an embodiment of the present inventive concept, a shape and a material of a channel layer, an insulating layer, a source/drain pattern, and the like may be controlled to provide a semiconductor device having improved electrical characteristics. Moreover, various advantages and effects of the present inventive concept may not be limited to the above, and will be more easily understood in the process of describing specific embodiments of the present inventive concept.

While example embodiments have been illustrated and described above, it will be apparent to those skilled in the art that modifications and variations could be made without departing from the scope of the present inventive concept as defined by the appended claims.

1. A semiconductor device, comprising:
a substrate;
a first insulating layer extending on the substrate;
source and drain patterns at spaced-apart locations on the first insulating layer;
a channel layer having a transition metal therein, said channel layer extending on the first insulating layer and between the source and drain patterns;
a second insulating layer, which extends on the channel layer and has a thickness less than a thickness of the first insulating layer; and
a gate structure extending on the second insulating layer, and opposite the channel layer.

2. The device of claim 1, wherein the channel layer comprises a transition metal dichalcogenide.

3. The device of claim 1, wherein the channel layer comprises at least one of MoS₂, WS₂, MoSe₂, WSe₂, MoSe₂, WTe₂, and ZrSe₂, and has a thickness of no more than three atomic layers.

4. The device of claim 1, wherein the thickness of the first insulating layer is about 3 angstroms to about 30 angstroms thicker than the thickness of the second insulating layer.

5. The device of claim 1, wherein the first insulating layer and the second insulating layer comprise hexagonal boron nitride (h-BN).

6. The device of claim 1, wherein the first insulating layer comprises hexagonal boron nitride (h-BN), and the second insulating layer comprises at least one of silicon oxide, silicon nitride, and silicon oxynitride.

7. The device of claim 1, wherein the source pattern is in contact with a first side surface of the channel layer and a first portion of an upper surface of the channel layer; and wherein the drain pattern is in contact with a second side surface of the channel layer and a second portion of the upper surface of the channel layer.

8. The device of claim 1, wherein at least a portion of the second insulating layer is disposed between the source pattern and the drain pattern.

9. The device of claim 1, wherein the source pattern and the drain pattern comprise a metal material.

10. The device of claim 9, wherein the source and drain patterns each comprise at least one of gold (Au), copper (Cu), nickel (Ni), silver (Ag), aluminum (Al), molybdenum (Mo), chromium (Cr), tantalum (Ta), titanium (Ti), and tungsten (W).

11. The device of claim 1, wherein the gate structure comprises:
a gate dielectric layer extending on the second insulating layer;
a gate electrode layer extending on the gate dielectric layer; and
gate spacer layers extending on at least side surfaces of the gate electrode layer.

12. The device of claim 11, wherein the gate dielectric layer comprises at least one of hafnium oxide (HfOx), hafnium aluminum oxide (HfAlOx), hafnium silicon oxide (HfSiOx), hafnium zirconium oxide (HfZrOx), hafnium yttrium oxide (HfYOx), and hafnium gadolinium oxide (HfGdOx).

13. A semiconductor device, comprising:
a substrate;
a first insulating layer extending on the substrate;
source and drain patterns at spaced apart locations on a surface of the first insulating layer that extends parallel to an upper surface of the substrate upon which the first insulating layer extends;
a channel layer extending on the surface of the first insulating layer and between the source and drain patterns, said channel layer having a thickness of no more than three atomic layers; and
a gate structure extending lengthwise in a second direction perpendicular to the first direction, said gate structure intersecting the channel layer and covering at least an upper surface and side surfaces of the channel layer.

14. The device of claim 13, wherein the channel layer includes a vertical portion extending in a direction that is perpendicular to the upper surface of the substrate, and a bottom portion extending from a lower end of the vertical portion in the first direction, parallel to the upper surface of the substrate.

15. The device of claim 14, wherein the first insulating layer includes a portion in which the channel layer extends to cover a side surface of the vertical portion.

16. The device of claim 14, further comprising a second insulating layer, which covers an upper surface of the bottom portion and a side surface of the vertical portion connected to the upper surface of the bottom portion.

17. The device of claim 13, wherein the gate structure comprises:
a gate insulating layer extending on the channel layer;
a gate dielectric layer extending on the gate insulating layer; and
a gate electrode layer extending on the gate dielectric layer,
wherein the first insulating layer and the gate insulating layer comprise hexagonal boron nitride (h-BN).

18. A semiconductor device, comprising:
a substrate;
a plurality of channel layers spaced apart from each other in a first direction, perpendicular to the substrate, and including a transition metal;
a source pattern and a drain pattern, arranged on both sides of the plurality of channel layers to contact the plurality of channel layers; and
a gate structure extending in a second direction, intersecting the plurality of channel layers on the substrate, and surrounding the plurality of channel layers, said gate structure comprising:
a gate insulating layer surrounding side surfaces of the channel layers and including hexagonal boron nitride (h-BN);
a gate dielectric layer surrounding an outer side surface of the gate insulating layer; and
a gate electrode layer surrounding an outer side surface of the gate dielectric layer.

19. The device of claim 18, wherein the plurality of channel layers comprise transition metal dichalcogenides having a two-dimensional structure.

20. The device of claim 18, wherein each of the source pattern and the drain pattern comprises a plurality of recesses formed within side surfaces adjacent to the plurality of channel layers; and wherein the plurality of channel layers are respectively disposed in the plurality of recesses.

21-24. (canceled)
